(19) United States
(12) Patent Application Publication
(10) Pub. No.: US 2026/0323212 A1
(43) Pub. Date: Oct. 15, 2026

(54) DYNAMIC POWER SUPPLY SHARING BETWEEN AMPLIFIERS

(71) Applicant: Texas Instruments Incorporated, Dallas, TX (US)

(72) Inventors: Rejin Kanjavalappil Raveendranath, Bangalore (IN); Lokesh Kumar Botcha, Bangalore (IN); Manojit Chakraborty, Bangalore (IN)

(21) Appl. No.: 19/423,349

(22) Filed: Dec. 17, 2025

(30) Foreign Application Priority Data
Apr. 11, 2025 (IN) 202541035401

(51) Int. Cl. H04R 5/04; G01R 19/04; H02M 3/157

(52) U.S. Cl. CPC H04R 5/04; G01R 19/04; H02M 3/157

(57) ABSTRACT

In an embodiment, an electronic circuit includes: a first voltage regulator; a first deserializer configured to receive a first signal that includes first data associated with a first channel; and a first controller configured to: identify a first temporal peak between a peak associated with the first data and a peak associated with second data associated with a second channel; and provide to the first voltage regulator a reference voltage that is based on the first temporal peak.

### CROSS-REFERENCE TO RELATED APPLICATION

This patent application claims the benefit of and priority to IN Provisional Patent Application No. 202541035401, filed Apr. 11, 2025, which is hereby incorporated herein by reference in its entirety.

### TECHNICAL FIELD

This description relates generally to electronic systems and methods, and, in particular embodiments, to dynamic power supply sharing between amplifiers.

### BACKGROUND

Electronic systems utilize amplifiers for a wide range of operations, such as for amplifying voltages of signals. In audio systems, audio amplifiers amplify voltages of an audio signal to produce an amplified signal at a relatively higher power. In operation, the audio amplifier provides the amplified signal to a speaker, which produces audible sound. Some audio systems have multiple audio channels to drive multiple speakers. Each audio channel includes an audio amplifier to amplify voltages of the audio signals on the respective audio channels.

Audio systems include a power converter to supply power to the audio amplifier. In some multi-channel audio systems, each audio amplifier receives power from a designated one of multiple power converters, which provides enough power to amplify audio signals across the channels. In other multi-channel audio systems, each audio amplifier receives power from a shared power converter, which provides enough power to amplify audio signals across the channels. In operation, the power converter(s) allow multi-channel audio systems to produce multiple amplified audio signals that produce a wide range of audible sound from multiple speakers.

### SUMMARY

In accordance to an embodiment, an electronic circuit includes: a first voltage regulator; a first deserializer configured to receive a first signal that includes first data associated with a first channel; and a first controller configured to: identify a first temporal peak between a peak associated with the first data and a peak associated with second data associated with a second channel; and provide to the first voltage regulator a reference voltage that is based on the first temporal peak.

In accordance to an embodiment, an apparatus includes: a first device including: a first input terminal; a first deserializer having an input coupled to the first input terminal and an output; and a first voltage regulator having an input and an output, the input of the first voltage regulator coupled to the output of the first deserializer; a second device including: a second input terminal; a second deserializer having an input and an output, the input of the second deserializer coupled to the second input terminal; and a second voltage regulator having an input and an output, the input of the second voltage regulator coupled to the output of the second deserializer, the output of the second voltage regulator coupled to the output of the first voltage regulator; a first amplifier having a data input and a supply input, the supply input of the first amplifier coupled to the outputs of the first and second voltage regulators, the data input of the first amplifier coupled to the output of the first deserializer; and a second amplifier having a data input and a supply input, the data input of the second amplifier coupled to the outputs of the first and second voltage regulators, the data input of the second amplifier coupled to the output of the second deserializer.

In accordance to an embodiment, a method includes: receiving first data and second data from a first serial input stream and a second serial input stream, respectively; identifying a first supply voltage corresponding to the first data is greater than or less than a second supply voltage corresponding to the second data; selecting the first supply voltage as a maximum supply voltage when the first supply voltage is greater than the second supply voltage; generating a regulator output voltage based on the selected first supply voltage; and amplifying the first and second data using the regulator output voltage.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a block diagram of an audio system having a first and second channel to power a first and second amplifier using multiple power converters, according to an embodiment of the present disclosure;

FIG. 2 is a schematic diagram of an implementation of the power converters of FIG. 1, according to an embodiment of the present disclosure;

FIG. 3 is a flowchart of an embodiment method for operating the power converters of FIGS. 1 and 2 or, more generally, the channels of FIG. 1 or, even more generally, the audio system of FIG. 1, according to an embodiment of the present disclosure;

FIG. 4 is a block diagram of another implementation of the audio system of FIG. 1 having a first and second channel that use a serializer and deserializer to communicate power supply values, according to an embodiment of the present disclosure;

FIG. 5 is a flowchart of an embodiment method for operating the serializer and deserializer of FIG. 4 and the channels of FIG. 4 or, more generally, the audio system of FIG. 4, according to an embodiment of the present disclosure;

FIG. 6 is a block diagram of another implementation of the audio system of FIG. 1 having a first and second channel that share a voltage reference between multiple power converters, according to an embodiment of the present disclosure;

FIG. 7 is a schematic diagram of an implementation of the power converters of FIG. 6, which share the voltage reference, according to an embodiment of the present disclosure.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates various specific details to provide an in-depth understanding of several example embodiments according to the description. The embodiments may be obtained without one or more of the specific details, or with other methods, components, materials and the like. In some cases, known structures, materials or operations are not shown or described in detail so as not to obscure the different aspects of the embodiments. References to “an embodiment” or “an example” in this description indicate that a particular configuration, structure or feature described in relation to the embodiment is included in at least one embodiment. Consequently, phrases such as “in one embodiment” or “in one example” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

Electronic systems utilize amplifiers for a wide range of operations, such as for amplifying voltages of signals. In audio systems, audio amplifiers amplify voltages of an audio signal to produce an amplified signal at a relatively higher power. In operation, the audio amplifier provides the amplified signal to a speaker, which produces audible sound. Some audio systems have multiple audio channels to drive multiple speakers. Each audio channel includes an audio amplifier to amplify voltages of the audio signal on the respective audio channels.

Audio systems have a power converter to supply power to the audio amplifier. In some multi-channel audio systems, each audio amplifier receives power from a designated one of multiple power converters, which provide enough power to amplify audio signals across the channels. In other multi-channel audio systems, each audio amplifier receives power from a shared power converter, which provides enough power to amplify audio signals across the channels. In operation, the power converter(s) allow multi-channel audio systems to produce multiple amplified signals that produce a wide range of audible sound from multiple speakers.

Some embodiments relate to methods and apparatus for dynamic power supply sharing between amplifiers. In some described examples, an example audio system includes multiple channels, amplifiers, and speakers. Each channel of the audio system has a power converter that produces a supply voltage (PVDD) responsive to a boost reference voltage (VREF_BOOST). The amplifiers receive the supply voltage (PVDD) from multiple power converters across different channels. For example, the outputs of the power converters are coupled together to form a supply terminal for multiple amplifiers. In such examples, the amplifiers are power sharing across the multiple power converters.

During power sharing operations, the channels use at least one of deserialized audio signals, a digital bus, or a shared reference terminal to produce a common supply voltage (PVDD) for the amplifiers. In one example, the channels deserialize audio signals for multiple channels to determine a peak across the multiple channels. In such examples, each channel determines the same peak and sets the supply voltage (PVDD) accordingly.

In another example, the channels determine a peak in the audio signal associated with each channel before reporting the peak value across a digital bus. In such examples, the channels determine a maximum peak value using peak values received on the digital bus. Similar to the first example, the channels determine the same peak and set the supply voltage (PVDD) accordingly.

In yet another example, the channels determine a peak in the audio signal associated with each channel. The channels set a reference terminal to a channel reference based on the determined peak. In such examples, the reference terminals of the channels are coupled together. In operation, the channel with the largest channel reference sets the voltage of the reference terminals. The power converters use the shared voltage of the reference terminals to generate the supply voltage (PVDD).

In some embodiments, using multiple power converters to generate a shared power supply advantageously allows the amplifiers to support a wide range of operating conditions without having each power converter support a maximum power output. For example, a first amplifier can use current from a first and second power converter to generate a local maximum and a second amplifier can use the remaining current from the second power converter to generate a relatively smaller signal. In such examples, neither the first nor second power converters need to be large enough to support generating the local maximum. Instead, sharing power across multiple power converters producing the same supply voltage reduces component sizes. In some embodiments, reducing the component sizes of the power converters advantageously reduces the system-on-chip (SoC) size of the channels or, more generally, the audio system.

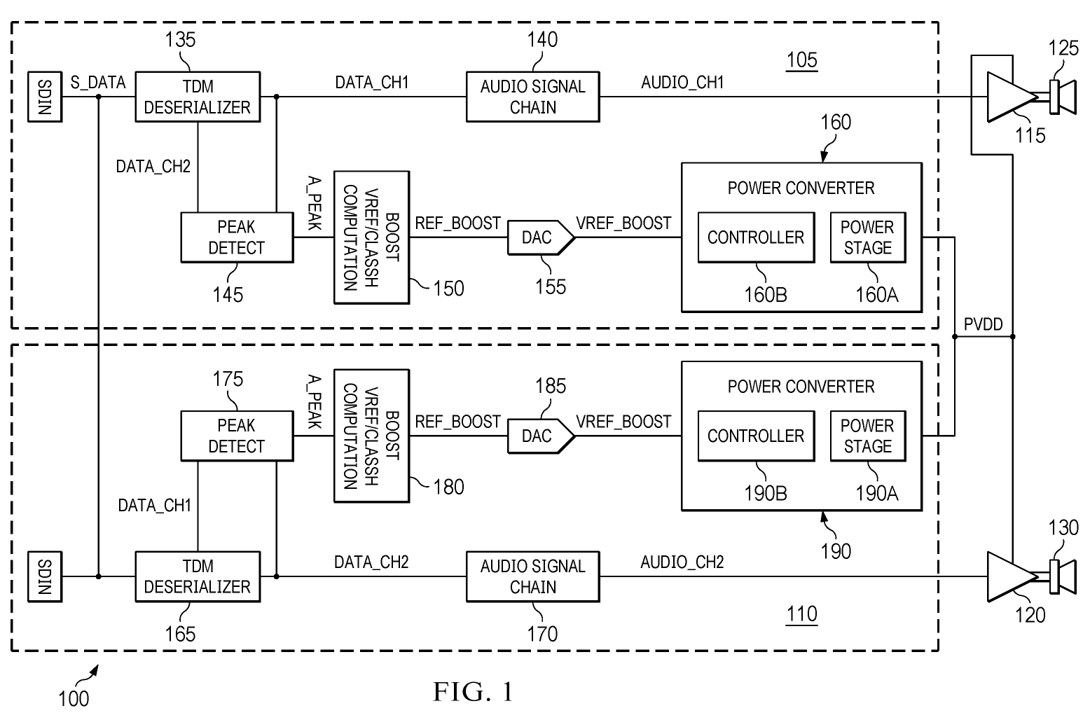

FIG. 1 is a block diagram of audio system 100, according to an embodiment of the present disclosure. In the example of FIG. 1, the audio system 100 includes channels 105, 110, amplifiers 115, 120, and speakers 125, 130. In the example of FIG. 1, the audio system 100 is an electronic circuit capable of being implemented in one or more integrated circuit(s) (IC), multi-chip modules, etc. For example, in an embodiment, a first IC has the channel 105, a second IC has the channel 110, a third IC has the amplifier 115, and a fourth IC has the amplifier 120. The audio system 100 receives a serial data stream (S_DATA) at a serial interface input (SDIN). The audio system 100 produces audible sound responsive to data of the serial data stream (S_DATA).

The channel 105 is coupled to the channel 110 and the amplifier 115. The channel 105 of FIG. 1 includes deserializer 135, audio signal chain circuitry 140, a peak detector 145, boost determination logic 150, a digital to analog converter (DAC) 155, and a power converter 160. The channel 105 receives the serial data stream (S_DATA) at an input terminal. The serial data stream (S_DATA) is a serial input stream of digital data representing multiple audio signals in a time multiplexed manner. The channel 105 generates an audio signal (AUDIO_CH1) and a supply voltage (PVDD) responsive to data of the serial data stream (S_DATA). The channel 105 provides the audio signal (AUDIO_CH1) to the amplifier 115. The channel 105 provides the supply voltage (PVDD) to the amplifiers 115, 120. In some examples, the supply voltage (PVDD) is referred to as a regulator output voltage.

In operation of the channel 105, the deserializer 135 deserializes the serial data stream (S_DATA) to produce audio data signals (DATA_CH1, DATA_CH2). The audio data signals (DATA_CH1, DATA_CH2) are digital audio signals that represent the serial data stream (S_DATA). In the example of FIG. 1, the audio data signals (DATA_CH1, DATA_CH2) represent audio for playback on a different one of the channels 105, 110. Alternatively, the deserializer 135 may deserialize any number (N) of audio data signals for audio systems having any number of channels. The audio signal chain 140 receives the audio data signal (DATA_CH1), which is a digital audio signal associated with the channel 105. The audio signal chain 140 conditions the audio data signal (DATA_CH1) to produce the audio signal (AUDIO_CH1). In some examples, the audio signal (AUDIO_CH1) is an analog audio signal. In some example operations, the audio signal chain 140 delays data of the audio signal (AUDIO_CH1) to account for delays of the peak detector 145, the boost determination logic 150, the DAC 155, and the power converter 160. In some such examples, the delay of the audio signal chain 140 allows the power converter 160 to adapt the supply voltage (PVDD) for a portion of the audio signal (AUDIO_CH1). The audio signal chain 140 provides the audio signal (AUDIO_CH1) to the amplifier 115.

In operation of the channel 105, the peak detector 145 receives the audio data signals (DATA_CH1, DATA_CH2) from the deserializer 135. The peak detector 145 determines an audio peak (A_PEAK) between the audio data signals (DATA_CH1, DATA_CH2). The audio peak (A_PEAK) represents a peak amplitude of audio corresponding to the audio data signals (DATA_CH1, DATA_CH2). In some examples, the peak detector 145 compares data of the audio data signals (DATA_CH1, DATA_CH2) across time to determine the audio peak (A_PEAK). In such examples, the peak detector 145 sets the audio peak (A_PEAK) as a temporal peak or local peak of the audio data signals (DATA_CH1, DATA_CH2). For example, the peak detector 145 is an envelope detector. The peak detector 145 provides the audio peak (A_PEAK) to the boost determination logic 150.

In operation of the channel 105, the boost determination logic 150 determines a value of the supply voltage (PVDD) that supports the audio peak (A_PEAK). The boost determination logic 150 may add headroom (additional voltage) to the determined value of the supply voltage (PVDD). In some examples, the boost determination logic 150 implements a class-H computation, which dynamically adjusts the supply voltage (PVDD) to track changes in the audio peak (A_PEAK). The boost determination logic 150 determines a boost reference value (REF_BOOST) corresponding to the determined value of the supply voltage (PVDD). The DAC 155 produces a boost reference voltage (VREF_BOOST) responsive to the boost reference value (REF_BOOST).

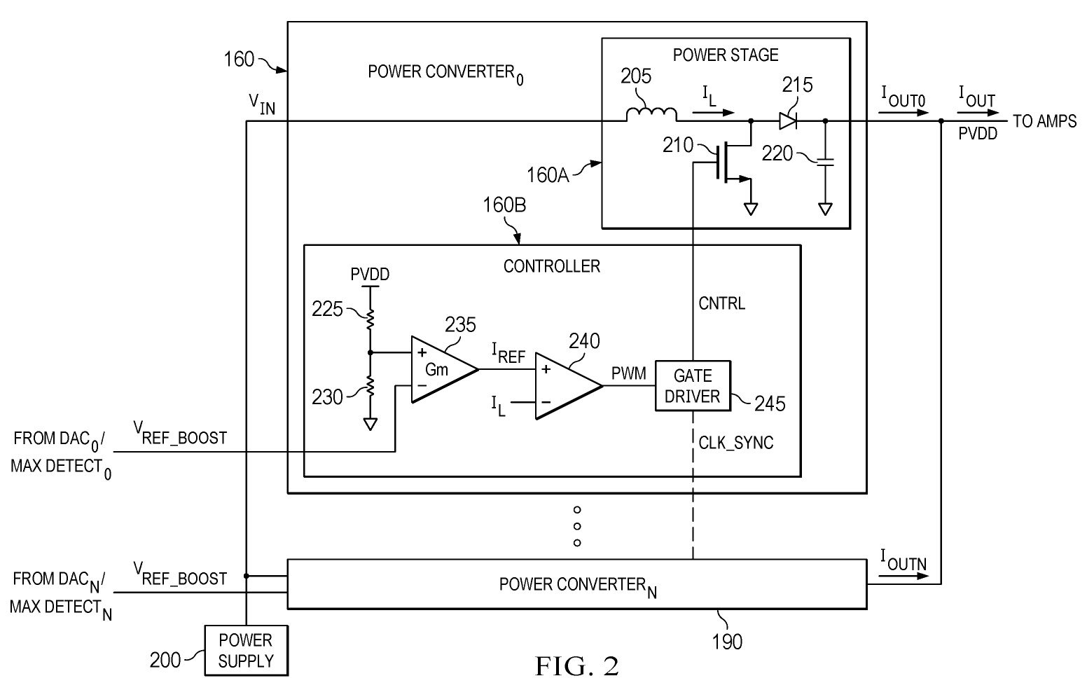

The power converter 160 receives the boost reference voltage (VREF_BOOST). In the example of FIG. 1, the power converter 160 of FIG. 1 includes a power stage 160A and a controller 160B. The power converter 160 produces the supply voltage (PVDD) responsive to the boost reference voltage (VREF_BOOST). In operation, the power stage 160A generates the supply voltage (PVDD) by regulating power from a power source (illustrated in FIG. 2). The controller 160B controls switching of the power stage 160A to regulate the supply voltage (PVDD) to be proportional to the boost reference voltage (VREF_BOOST). The power converter 160 provides the supply voltage (PVDD) to the amplifiers 115, 120. In some examples, the power converter 160 is referred to as a boost switching converter or a voltage regulator. Examples of the power stage 160A and the controller 160B or, more generally, the power converter 160 are illustrated and described in connection with FIG. 2.

The channel 110 is coupled to the channel 105 and the amplifier 120. The channel 110 of FIG. 1 includes deserializer 165, audio signal chain circuitry 170, a peak detector 175, boost determination logic 180, a DAC 185, and a power converter 190. The channel 110 receives the serial data stream (S_DATA) at an input terminal. The channel 110 generates an audio signal (AUDIO_CH2) and the supply voltage (PVDD) responsive to data of the serial data stream (S_DATA). The channel 110 provides the audio signal (AUDIO_CH2) to the amplifier 120. The channel 110 provides the supply voltage (PVDD) to the amplifiers 115, 120.

In operation of the channel 110, the deserializer 165 deserializes the serial data stream (S_DATA) to produce the audio data signals (DATA_CH1, DATA_CH2). Unlike the audio signal chain 140, the audio signal chain 170 receives the audio data signal (DATA_CH2), which corresponds to audio of the channel 110. The audio signal chain 170 conditions the audio data signal (DATA_CH2) to produce the audio signal (AUDIO_CH2). In some examples, the audio signal (AUDIO_CH2) is an analog audio signal. The audio signal chain 170 provides the audio signal (AUDIO_CH2) to the amplifier 120.

In operation of the channel 110, the peak detector 175 receives the audio data signals (DATA_CH1, DATA_CH2) from the deserializer 165. The peak detector 175 determines an audio peak (A_PEAK) between the audio data signals (DATA_CH1, DATA_CH2). Ideally, the peak detectors 145, 175 produce the same audio peak (A_PEAK) simultaneously. In such operations, the peak detectors 145, 175 compare the same data of the audio data signals (DATA_CH1, DATA_CH2) across the same time to determine the audio peak (A_PEAK). In some examples, the peak detectors 145, 175 are envelope detectors, windowing circuitry, etc. The peak detector 175 provides the audio peak (A_PEAK) to the boost determination logic 180.

In operation of the channel 110, the boost determination logic 180 determines the value of the supply voltage (PVDD) that supports the audio peak (A_PEAK). If the peak detectors 145, 175 determine the same value of the audio peak (A_PEAK), the boost determination logic 180 determines the same value of the supply voltage (PVDD) as the boost determination logic 150. Accordingly, the boost determination logic 150, 180 produce the boost reference value (REF_BOOST) corresponding to the determined value of the supply voltage (PVDD). The DAC 185 produces the boost reference voltage (VREF_BOOST) responsive to the boost reference value (REF_BOOST).

The power converter 190 receives the boost reference voltage (VREF_BOOST). In the example of FIG. 1, the power converter 190 of FIG. 1 includes a power stage 190A and a controller 190B. Similar to the power converter 160 of the channel 105, the power converter 190 produces the supply voltage (PVDD) responsive to the boost reference voltage (VREF_BOOST). In operation, the power stage 190A generates the supply voltage (PVDD) by regulating power from a power source (illustrated in FIG. 2). The controller 190B controls switching of the power stage 190A to regulate the supply voltage (PVDD) to be proportional to the boost reference voltage (VREF_BOOST). The power converter 190 provides the supply voltage (PVDD) to the amplifiers 115, 120. Examples operations of the power converter 160 are further described in connection with FIG. 2.

The amplifier 115 is coupled to the channels 105, 110 and the speaker 125. The amplifier 115 receives the audio signal (AUDIO_CH1) at a data input and the supply voltage (PVDD) at a supply input (also referred to as a supply terminal). The amplifier 115 uses power from the power converters 160, 190 to generate amplified signals that reproduce data of the audio signal (AUDIO_CH1) at relatively higher voltages in comparison to the audio signal (AUDIO_CH1). The amplifier 115 drives the speaker 125 using the amplified signals. The speaker 125 produces audible sound responsive to the amplified signals.

The amplifier 120 is coupled to the channels 105, 110 and the speaker 125. The amplifier 120 receives the audio signal (AUDIO_CH2) at a data input and the supply voltage (PVDD) at a supply input (also referred to as a supply terminal). The amplifier 120 uses power from the power converters 160, 190 to generate amplified signals at relatively higher voltages in comparison to the audio signal (AUDIO_CH2). The amplifier 120 drives the speaker 130 using the amplified signals. The speaker 130 produces audible sound responsive to the amplified signals.

In some embodiments, the power converters 160, 190 adjust the supply voltage (PVDD) in relation to the audio peak (A_PEAK) of the audio signals (AUDIO_CH1, AUDIO_CH2) at outputs of the channels 105, 110. In some embodiments, adjusting the supply voltage (PVDD) with the audio signals (AUDIO_CH1, AUDIO_CH2) advantageously improves power efficiency. In some embodiments, the amplifiers 115, 120 can use current from both of the power converters 160, 190 to produce amplified signals from the audio signals (AUDIO_CH1, AUDIO_CH2). For example, if the audio signal (AUDIO_CH1) of the channel 105 has the audio peak (A_PEAK), the amplifier 115 uses current from both of the power converters 160, 190 to generate the corresponding amplified signal. In some embodiments, sharing the supply of power to the amplifiers 115, 120 between the power converters 160, 190 advantageously reduces the size of the power stages 160A, 190A. Example operations of power sharing between the power converters 160, 190 are further described in connection with FIG. 2. In some embodiments, decreasing the size of the power stages 160A, 190A advantageously decreases component values and system-on-chip (SoC) size of the power converters 160, 190.

FIG. 2 is a schematic diagram of an example implementation of the power converters 160, 190 of FIG. 1, according to an embodiment of the present disclosure. The power converters 160, 190 receive the boost reference voltage (VREF_BOOST) from the DACs 155, 185 and an input voltage (V_{IN}) from a power supply 200. The power converters 160, 190 provide a supply current (I_{OUT}) and the supply voltage (PVDD) by converting power from the power supply 200. The power supply 200 is coupled to the power converters 160, 190. The power supply 200 provides the input voltage (V_{IN}). In operation, the power supply 200 additionally supplies current to the power converters 160, 190. The power converter 160, 190 regulate the current from the power supply 200 to produce the supply voltage (PVDD) and the supply current (I_{OUT}). In some examples, the power supply 200 is an energy storage device, such as a battery. In other examples, the power supply 200 is a power regulator, which regulates power from a power source, such as a grid connection. In both examples, the power supply 200 varies a current to supply the input voltage (V_{IN}) to the power converters 160, 190.

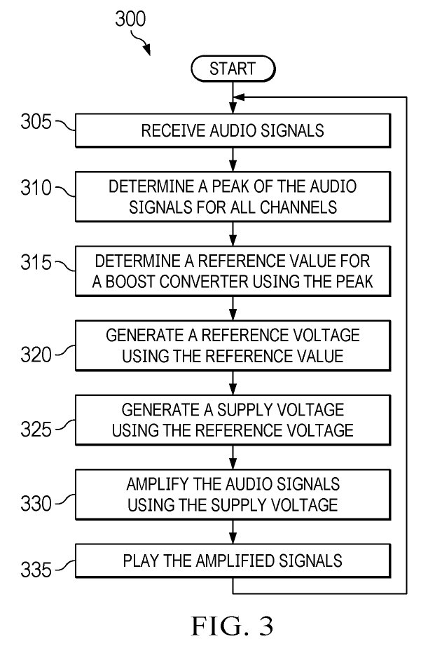

In the example of FIG. 2, the power stage 160A and the controller 160B of the power converter 160 are illustrated and described. In the example of FIG. 3, components of the power converter 160 are illustrated and described. However, it is to be understood that, in some embodiments, the power converter 190 is an instance of the power converter 160, which contains similar components to those illustrated in connection with the power converter 160. For example, the power stage 190A and the controller 190B have similar components and operations as the power stage 160A and the controller 160B of FIG. 2.

The power stage 160A is coupled to the controller 160B, the power converter 190, and the power supply 200. The example power stage 160A of FIG. 2 includes an inductor 205, a transistor 210, a diode 215, and a capacitor 220. The power stage 160A receives the input voltage (V_{IN}) and a control signal (CNTRL). The power stage 160A produces the supply voltage (PVDD) and a stage supply current (I_{OUT0}) by regulating power from the power supply 200 responsive to the control signal (CNTRL).

In operation, the transistor 210 sinks a current (I_{L}) from the inductor 205 responsive to the control signal (CNTRL). When conducting (e.g., turned on), the transistor 210 sinks the current (I_{L}) from the inductor 205, which allows the capacitor 220 to discharge. When non-conducting (e.g., turned off), the transistor 210 allows the current (I_{L}) from the inductor 205 to charge the capacitor 220 and drive a load. The capacitor 220 sets the supply voltage (PVDD) using charge from the current (I_{L}) of the inductor 205. In some examples, such as in FIG. 2, the power stage 160A has the diode 215. In some such examples, the diode 215 prevents current from the power converter 190 or the capacitor 220 from being supplied to the inductor 205.

In such operations, a duty cycle or on time of the control signal (CNTRL) controls the charging of the capacitor 220. Thus, the supply voltage (PVDD) corresponds to the duty cycle of the control signal (CNTRL). For example, decreasing the on time of the transistor 210 increases the charge of the capacitor 220 and the supply voltage (PVDD). Alternatively, increasing the on time of the transistor 210 decreases the charge of the capacitor 220 and the supply voltage (PVDD).

In the example of FIG. 2, the transistor 210 is an n-channel metal-oxide semiconductor field-effect transistor (MOSFET). Alternatively, the transistor 210 may be an n-channel field-effect transistor (FET), an n-channel insulated-gate bipolar transistor (IGBT), an n-channel junction field effect transistor (JFET), an NPN bipolar junction transistor (BJT) or, with slight modifications, a p-type equivalent device. The transistor 210 may be a depletion mode device, a drain-extended device, an enhancement mode device, a natural transistor or other type of device structure transistor. Furthermore, the transistor 210 may be implemented in/over a silicon substrate (Si), a silicon carbide substrate (SiC), a gallium nitride substrate (GaN) or a gallium arsenide substrate (GaAs).

The controller 160B is coupled to the power stage 160A and the power converter 190. The example controller 160B of FIG. 2 includes resistors 225, 230, amplifiers 235, 240, and a gate driver 245. The controller 160B receives the reference boost voltage (VREF_BOOST), the supply voltage (PVDD), and the current (I_{L}). The controller 160B generates the control signal (CNTRL) by comparing the supply voltage (PVDD) and the current (I_{L}) to the reference boost voltage (VREF_BOOST).

In operation, the resistors 225, 230 form a voltage divider, which steps down the supply voltage (PVDD) by a scaling factor. The scaling factor between the resistors 225, 230 is set to decrease the supply voltage (PVDD) to a voltage supported by the amplifiers 235, 240. The amplifier 235 compares the scaled supply voltage to the reference boost voltage (VREF_BOOST). In some examples, the amplifier 235 is referred to as a transconductance amplifier or error circuitry, which produces a reference current (I_{REF}). The reference current (I_{REF}) is proportional to the difference between the reference boost voltage (VREF_BOOST) and the scaled supply voltage. Such reference current (I_{REF}) may also be referred to as an error current.

In such operations, the amplifier 240 compares the reference current (I_{REF}) to the current (I_{L}) through the inductor 205. In some examples, the power stage 160A includes current sense circuitry to determine the current (I_{L}). The amplifier 240 generates a pulse width modulation (PWM) signal responsive to a determination that the current (I_{REF}) is greater than or less than the current (I_{L}). The PWM signal represents a determination by the amplifiers 235, 240 whether to turn on the transistor 210. For example, the amplifiers 235, 240 set the PWM signal to a logic high responsive to a determination that the supply voltage (PVDD) is a threshold greater than the reference boost voltage (VREF_BOOST). The gate driver 245 generates the control signal (CNTRL) using the PWM signal from the amplifier 240. In some examples, the gate driver 245 shift the logic of the PWM signal to control the transistor 210. For example, the gate driver 245 may shift edges of the PWM signal responsive to a clock sync signal (CLK_SYNC). The clock sync signal (CLK_SYNC) is common to the power converters 160, 190, which allows the instances of the gate driver 245 or, more generally, the controller 160B to synchronize a switching phase of the control signals (CNTRL).

In some embodiments, the amplifiers 235, 240 generate the control signal (CNTRL) using a comparison of the supply voltage (PVDD) and the current (I_{L}) to the reference boost voltage (VREF_BOOST). In such embodiments, the amplifiers 235, 240 adjust the supply voltage (PVDD) responsive to changes in the reference boost voltage (VREF_BOOST). In some such embodiments, if the power converters 160, 190 receive the same reference boost voltage (VREF_BOOST), the power converters 160, 190 advantageously generate the same supply voltage with a supply current (I_{OUT}) equal to the combination of the stage supply currents (I_{OUT0}, I_{OUTN}). In some embodiments, by sharing an output, the power converters 160, 190 are capable of supplying power greater than the power supply 200 provides to either of the power converters 160, 190. In some embodiments, dividing the power at the output of the power converters 160, 190 between the power converters 160, 190 advantageously allows the respective ones of the power stage 160A to have a relatively smaller inductance of the inductor 205. In such example embodiments, decreasing the size of the inductor 205 advantageously decreases the system-on-chip (SoC) size of the power converters 160, 190.

FIG. 3 is a flowchart of embodiment method 300, according to an embodiment of the present disclosure. Method 300 may be implemented or performed by power converters 160, 190 of FIGS. 1 and 2 or, more generally, the channels 105, 110 of FIG. 1 or, even more generally, the audio system 100 of FIG. 1. Method 300 begin with Block 305, at which, the channels 105, 110 receive audio signals. In some examples, the channels 105, 110 receive a serial data stream (S_DATA) at a serial interface input (SDIN). The serial data stream (S_DATA) represents multiple audio signals that have serialized into a single signal. In operation, the deserializers 135, 165 deserialize the serial data steam (S_DATA) to produce the audio data signals (DATA_CH1, DATA_CH2). In such operations, each of the channels 105, 110 corresponds to one of the audio data signals (DATA_CH1, DATA_CH2). For example, the channel 105 corresponds to the audio data signal (DATA_CH1) and the channel 110 corresponds to the audio data signal (DATA_CH2). The audio data signals (DATA_CH1, DATA_CH2) represent audio to be produced by the speakers 125, 130.

The peak detectors 145, 175 determines a peak of the audio signals for all channels. (Block 310). In operation, the peak detectors 145, 175 receive both of the audio data signals (DATA_CH1, DATA_CH2) from the deserializers 135, 165. The peak detectors 145, 175 detect a temporal peak of the audio data signals (DATA_CH1, DATA_CH2). In some examples, the temporal peak of the audio data signals (DATA_CH1, DATA_CH2) is referred to as the audio peak (A_PEAK). The audio peak represents a local maximum value between the audio data signals (DATA_CH1, DATA_CH2) for a given instance of time. In some examples, the peak detectors 145, 175 are an envelope detector, sliding window circuitry, etc.

The boost determination logic 150, 180 determines a reference value for a boost converter using the peak. (Block 315). In operation, the boost determination logic 150, 180 implements a class-H computation, which dynamically adjusts the supply voltage (PVDD) to track changes in the audio peak (A_PEAK). The boost determination logic 150, 180 determines the boost reference value (REF_BOOST) corresponding to the determined value of the supply voltage (PVDD).

The DACs 155, 185 generate a reference voltage using the reference value. (Block 320). In operation, the DACs 155, 185 produces boost reference voltage (VREF_BOOST) responsive to the boost reference value (REF_BOOST) from the boost determination logic 150, 180. In some examples, the boost reference value (REF_BOOST) is a DAC code, which represents the boost reference voltage (VREF_BOOST) as a digital value. In such examples, the DACs 155, 185 provide the boost reference voltage (VREF_BOOST) to the power converters 160, 190.

The power converters 160, 190 generate a supply voltage using the reference voltage. (Block 325). In operation, the power stages 160A, 190A regulate power from the power supply 200 to generate the supply voltage (PVDD) and the supply current (IOUT) responsive to the controllers 160B, 190B. The controllers 160B, 190B control the powers stages 160A, 190A by comparing the boost reference voltage (VREF_BOOST) to the supply voltage (PVDD). In some embodiments, the power converters 160, 190 provide the supply voltage (PVDD) and the supply current (I_{OUT}) at a shared output.

The amplifiers 115, 120 amplify the audio signals using the supply voltage. (Block 330). In operation, the power converters 160, 190 power the amplifiers 115, 120 using the supply voltage (PVDD) and the supply current (I_{OUT}). The amplifiers 115, 120 share power from the power converters 160, 190 to amplify the audio signals (AUDIO_CH1, AUDIO_CH2). In some embodiments, the power converters 160, 190 set the supply voltage (PVDD) and the supply current (I_{OUT}) responsive to the boost reference voltage (VREF_BOOST), which advantageously corresponds to a determined peak in the audio signals (AUDIO_CH1, AUDIO_CH2).

In some embodiments, despite sharing power from the power converters 160, 190, the amplifiers 115, 120 advantageously maintain a full range of support for the audio peak (A_PEAK). In some embodiments, the capacitor 220 advantageously allows the amplifiers 115, 120 to briefly consume more power than provided based on the boost reference voltage (VREF_BOOST). During such operations, the amplifiers 115, 120 use additional charge from the capacitor 220 to compensate for the additional power consumption. In some embodiments, by sharing a power supply, the amplifiers 115, 120 can advantageously amplify the audio signals (AUDIO_CH1, AUDIO_CH2) across a wider range of conditions, such as power levels, error, etc.

The speakers 125, 130 play the audio signals. (Block 335). In operation, the speakers 125, 130 produce soundwaves responsive to the amplified signals from the amplifiers 115, 120. In some examples, if the soundwaves have frequencies in the audible spectrum (e.g., 20 Hz to 20 kHz), the speakers 125, 130 produce audible sound. In another example, the speakers 125, 130 are haptic devices, which produce soundwaves having relatively low frequency (e.g., 50 Hz to 500 Hz), for simulating vibrations. In yet another example, the speakers 125, 130 produce ultra sonic signals having frequencies in the ultrasonic spectrum (e.g., greater than 20 kHz) for ultrasonic sensing. Control proceeds to return to Block 305.

Although example methods are described with reference to the flowchart illustrated in FIG. 3, many other methods of implementing the power converters 160, 190 of FIGS. 1 and 2 or, more generally, the channels 105, 110 of FIG. 1 or, even more generally, the audio system 100 of FIG. 1 may alternatively be used in this description. For example, the order of execution of the blocks may be changed, and/or some of the blocks described may be changed, eliminated, or combined. Similarly, additional operations may be included in the manufacturing process before, in between, or after the blocks shown in the illustrated examples.

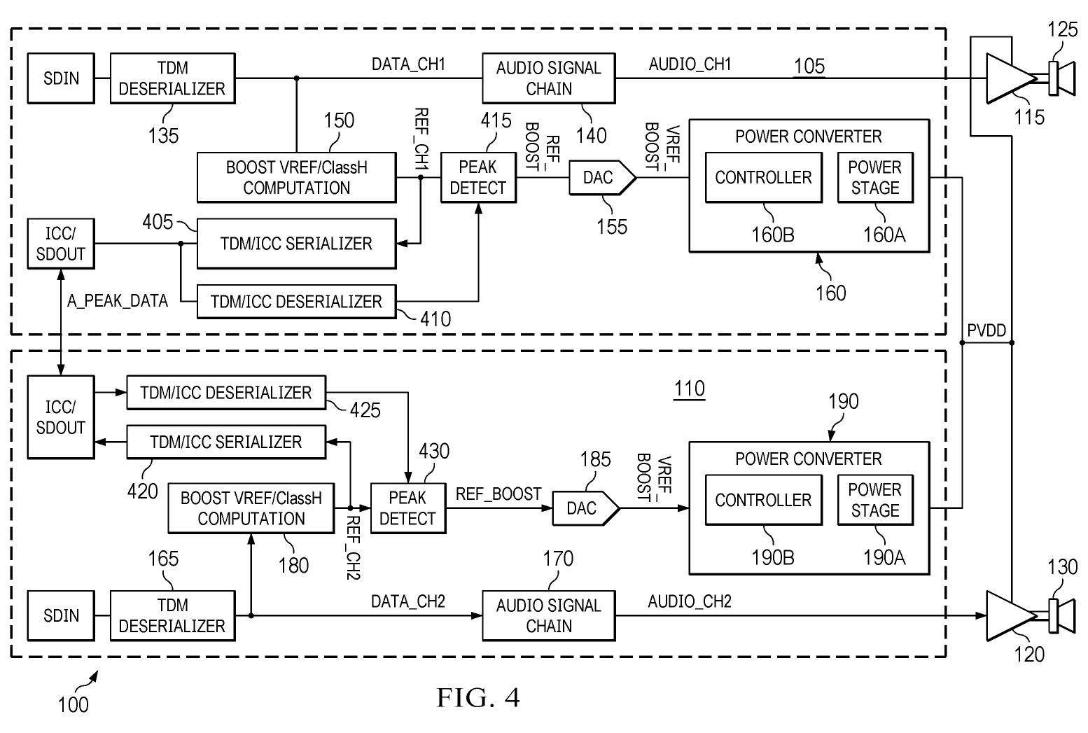

FIG. 4 is a block diagram of another example of the audio system 100 of FIG. 1 having the channels 105, 110, according to an embodiment of the present disclosure. In the example of FIG. 4, the audio system 100 includes the channels 105, 110, the amplifiers 115, 120, and the speakers 125, 130. The audio system 100 of FIG. 4 receives a serial data stream (S_DATA) at a serial interface input (SDIN). Unlike in the example of FIG. 1, the audio system 100 of FIG. 4 uses an additional communication interface (ICC/SDOUT) to communicate between the channels 105, 110. As further described below, the channels 105, 110 use the additional communication interface (ICC/SDOUT) to report the audio peak (A_PEAK) of each channel. In some examples, the additional communication interface (ICC/SDOUT) is referred to as a digital bus. The audio system 100 produces audible sound responsive to data of the serial data stream (S_DATA) and the audio peaks (A_PEAK) reported on the additional communication interface (ICC/SDOUT).

The channel 105 is coupled to the channel 110 and the amplifier 115. The example channel 105 of FIG. 4 includes the deserializer 135, the audio signal chain circuitry 140, the boost determination logic 150, the DAC 155, the power converter 160, a serializer 405, a deserializer 410, and a peak detector 415. The channel 105 receives the serial data stream (S_DATA) and audio peak data (A_PEAK_DATA). The channel 105 generates an audio signal (AUDIO_CH1), a supply voltage (PVDD), and audio peak data (A_PEAK_DATA) responsive to data of the serial data stream (S_DATA). The channel 105 provides the audio signal (AUDIO_CH1) to the amplifier 115. The channel 105 provides the supply voltage (PVDD) to the amplifiers 115, 120. The channel 105 provides the audio peak data (A_PEAK_DATA) to the channel 110 or, more generally, the communication interface (ICC/SDOUT).

In operation, the boost determination logic 150 determines the supply voltage (PVDD) to support the audio data signal (DATA_CH1). The boost determination logic 150 generates a channel reference (REF_CH1) representing the determined supply voltage needed for the audio data signal (DATA_CH1). In some examples, the channel reference (REF_CH1) is a reference code, which corresponds to a specific voltage at the output of the DAC 155. The serializer 405 communicates the channel reference (REF_CH1) across the communication interface (ICC/SDOUT). In some examples, the communication interface (ICC/SDOUT) allows any number (N) of channels to communicate any number of channel references using the communication interface (ICC/SDOUT). In such examples, the serializer 405 establishes a serial output stream to communicate the channel reference (REF_CH1). The deserializer 410 receives a channel reference (REF_CH2) of the channel 110 from the communication interface (ICC/SDOUT). The deserializer 410 provides the channel reference (REF_CH2) to the peak detector 415.

In such operations, the peak detector 415 receives the channel references (REF_CH1, REF_CH2) from the boost determination logic 150 and the deserializer 410. The peak detector 415 produces the boost reference value (REF_BOOST) responsive to a comparison of the channel references (REF_CH1, REF_CH2). For example, the peak detector 415 sets the boost reference value (REF_BOOST) to the largest of the channel references (REF_CH1, REF_CH2), which corresponds to the maximum supply voltage. In some examples, the peak detector 415 may compare channel references across a temporal period of time. In such examples, the boost reference value (REF_BOOST) represents the supply voltage (PVDD) for an audio peak (A_PEAK) over a period of time. Similar to the example channel 105 of FIG. 1, the DAC 155 and the power converter 160 produce the supply voltage (PVDD) responsive to the boost reference value (REF_BOOST).

The channel 110 is coupled to the channel 105 and the amplifier 120. The example channel 110 of FIG. 4 includes the deserializer 165, the audio signal chain circuitry 170, the boost determination logic 180, the DAC 185, the power converter 190, a serializer 420, a deserializer 425, and a peak detector 430. The channel 110 receives the serial data stream (S_DATA) and the audio peak data (A_PEAK_DATA). The channel 110 generates an audio signal (AUDIO_CH2), the supply voltage (PVDD), and the audio peak data (A_PEAK_DATA) responsive to data of the serial data stream (S_DATA). The channel 110 provides the audio signal (AUDIO_CH2) to the amplifier 120. The channel 110 provides the supply voltage (PVDD) to the amplifiers 115, 120. The channel 110 provides the audio peak data (A_PEAK_DATA) to the channel 105 or, more generally, the communication interface (ICC/SDOUT).

In operation, the boost determination logic 180 determines the supply voltage (PVDD) to support the audio data signal (DATA_CH2). The boost determination logic 180 generates a channel reference (REF_CH2) representing the determined supply voltage needed for the audio data signal (DATA_CH2). In some examples, the channel reference (REF_CH2) is a reference code, which corresponds to a specific voltage at the output of the DAC 185. The serializer 420 communicates the channel reference (REF_CH2) across the communication interface (ICC/SDOUT). The deserializer 425 receives the channel reference (REF_CH1) of the channel 105 from the communication interface (ICC/SDOUT). The deserializer 425 provides the channel reference (REF_CH1) to the peak detector 430.

In such operations, the peak detector 430 receives the channel references (REF_CH1, REF_CH2) from the boost determination logic 180 and the deserializer 425. The peak detector 430 produces the boost reference value (REF_BOOST) responsive to a comparison of the channel references (REF_CH1, REF_CH2). For example, the peak detector 430 sets the boost reference value (REF_BOOST) to the largest of the channel references (REF_CH1, REF_CH2). In some examples, the peak detector 430 may compare channel references across a temporal period of time. In such examples, the boost reference value (REF_BOOST) represents the supply voltage (PVDD) for an audio peak (A_PEAK) over a period of time. Similar to the example channel 110 of FIG. 1, the DAC 185 and the power converter 190 produce the supply voltage (PVDD) responsive to the boost reference value (REF_BOOST).

In some embodiments, the deserializers 135, 165 only deserialize a respective one of the audio data signals (DATA_CH1, DATA_CH2) responsive to using the communication interface (ICC/SDOUT) to communicate channer references (REF_CH1, REF_CH2). In some embodiments, the peak detectors 415, 430 select the same one of the channel references (REF_CH1, REF_CH2) to advantageously produce the boost reference value (REF_BOOST). In such embodiments, if the peak detectors 415, 430 produce the same boost reference value (REF_BOOST), the power converters 160, 190 generate a common supply voltage (PVDD), which advantageously has a boosted supply current (I_{OUT}). In some embodiments, the amplifiers 115, 120 share power from the power converters 160, 190 to amplify the audio signals (AUDIO_CH1, AUDIO_CH2). In such embodiments, using power from both of the power converters 160, 190 advantageously allow the amplifiers 115, 120 to support a wider range of operations without increasing the components of the power converters 160, 190.

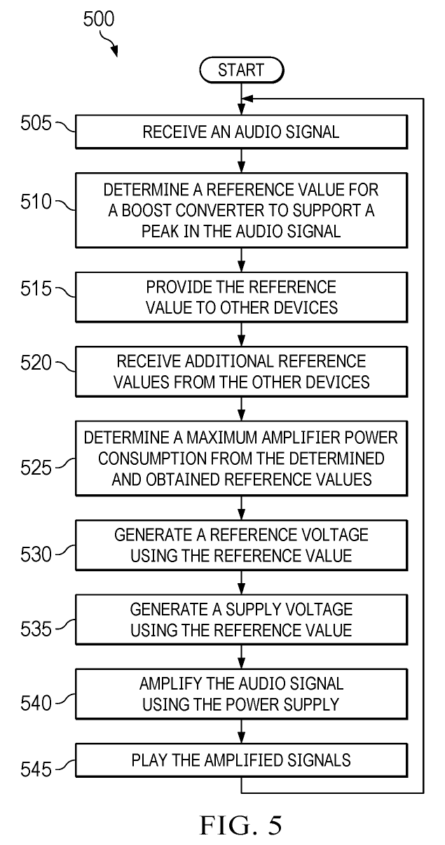

Example operations of the audio system 100 of FIG. 4 are further illustrated and described in connection with FIG. 5.

FIG. 5 is a flowchart of embodiment method 500, according to an embodiment of the present disclosure. Method 500 may be implemented or performed by serializers 405, 420 and the deserializers 410, 425 of FIG. 4 and the channels 105, 110 of FIG. 4 or, more generally, the audio system 100 of FIG. 4. Method 500 begin at Block 505 at which, the channels 105, 110 receive an audio signal. In some examples, the channels 105, 110 receive a serial data stream (S_DATA) at a serial interface input (SDIN). The serial data stream (S_DATA) represents multiple audio signals that have serialized into a single signal. In operation, the deserializers 135, 165 deserialize the serial data steam (S_DATA) to produce a respective one of the audio data signals (DATA_CH1, DATA_CH2). In such operations, each of the channels 105, 110 corresponds to one of the audio data signals (DATA_CH1, DATA_CH2). For example, the channel 105 deserializes the audio data signal (DATA_CH1) and the channel 110 deserializes the audio data signal (DATA_CH2). The audio data signals (DATA_CH1, DATA_CH2) represent audio to be produced by the speakers 125, 130.

The boost determination logic 150, 180 determines a reference value for a boost converter to support a peak in the audio signal. (Block 510). In operation, the boost determination logic 150, 180 determines a supply voltage (PVDD) to support the respective one of the audio data signals (DATA_CH1, DATA_CH2). The boost determination logic 150, 180 determines the channel references (REF_CH1, REF_CH2) that represent the determined supply voltage (PVDD). For example, the boost determination logic 150 determines the channel reference (REF_CH1) corresponds to the audio data signal (DATA_CH1). Similarly, the boost determination logic 180 determines the channel reference (REF_CH2) corresponds to the audio data signal (DATA_CH2). In such operations, the boost determination logic 150, 180 update the channel references (REF_CH1, REF_CH2) responsive to changes in the audio data signals (DATA_CH1, DATA_CH2).

The serializers 405, 420 provide the reference values to other devices. (Block 515). In operation, the serializes 405, 420 use a shared communication interface (ICC/SDOUT) between all devices (also referred to as channels) of the audio system 100 to report the channel references (REF_CH1, REF_CH2). In some examples, the serializers 405, 420 use a communication protocol, such as I2C, to exchange/report the channel references (REF_CH1, REF_CH2) periodically.

The deserializers 410, 425 receive additional reference values from the other devices. (Block 520). In operation, the deserializers 410, 425 use the shared communication interface (ICC/SDOUT) between devices of the audio system 100 to receive the channel references (REF_CH1, REF_CH2) of other ones of the channels 105, 110. For example, the deserializer 410 receives the channel reference (REF_CH2) from the serializer 420. The deserializers 410, 425 provide the channel references (REF_CH1, REF_CH2) to the peak detectors 415, 430.

The peak detectors 415, 430 determine a maximum amplifier power consumption from the determined and obtained reference values. (Block 525). In operation, the peak detectors 415, 430 compare the channel references (REF_CH1, REF_CH2) to determine a peak supply voltage. In some examples, the peak detectors 415, 430 select the largest of the channel references as corresponding to the peak supply voltage. The peak detectors 415, 430 set the boost reference value (REF_BOOST) responsive to the comparison.

The DACs 155, 185 generate a reference voltage using the reference value. (Block 530). In operation, the DACs 155, 185 produces boost reference voltage (VREF_BOOST) responsive to the boost reference value (REF_BOOST) from the peak detectors 415, 430. In some examples, the boost reference value (REF_BOOST) is a DAC code, which represents the boost reference voltage (VREF_BOOST) as a digital value. In such examples, the DACs 155, 185 provide the boost reference voltage (VREF_BOOST) to the power converters 160, 190.

The power converters 160, 190 generate a supply voltage using the reference value. (Block 535). In operation, the power stages 160A, 190A regulate power from the power supply 200 to generate the supply voltage (PVDD) and the supply current (IOUT) responsive to the controllers 160B, 190B. The controllers 160B, 190B control the powers stages 160A, 190A by comparing the boost reference voltage (VREF_BOOST) to the supply voltage (PVDD). In some embodiments, the power converters 160, 190 provide the supply voltage (PVDD) and the supply current (I_{OUT}) at a shared output.

The amplifiers 115, 120 amplify the audio signal using the power supply. (Block 540). In operation, the power converters 160, 190 power the amplifiers 115, 120 using the supply voltage (PVDD) and the supply current (I_{OUT}). The amplifiers 115, 120 share power from the power converters 160, 190 to amplify the audio signals (AUDIO_CH1, AUDIO_CH2). In some embodiments, the power converters 160, 190 set the supply voltage (PVDD) and the supply current (I_{OUT}) responsive to the boost reference voltage (VREF_BOOST), which advantageously corresponds to a determined peak in the audio signals (AUDIO_CH1, AUDIO_CH2).

In some embodiments, despite sharing power from the power converters 160, 190, the amplifiers 115, 120 advantageously maintain a full range of support for the audio peak (A_PEAK). In some embodiments, the serializers 405, 420 and the deserializers 410, 425 advantageously allow the channels 105, 110 to determine the audio peak (A_PEAK) without having to deserialize and process both of the audio data signals (DATA_CH1, DATA_CH2). In some embodiments, using the shared communication interface (ICC/SDOUT) advantageously decreases the complexity of power sharing as the number of channels increases. In such embodiments, by sharing a power supply, the amplifiers 115, 120 can advantageously amplify the audio signals (AUDIO_CH1, AUDIO_CH2) across a wider range of conditions, such as power levels, error, etc.

The speakers 125, 130 play the amplified signals. (Block 545). In operation, the speakers 125, 130 produce soundwaves responsive to the amplified signals from the amplifiers 115, 120. In some examples, if the soundwaves have frequencies in the audible spectrum (e.g., 20Hz to 20kHz), the speakers 125, 130 produce audible sound. In another example, the speakers 125, 130 are haptic devices, which produce soundwaves having relatively low frequency (e.g., 50Hz to 500Hz), for simulating vibrations. In some such examples, the channels 105, 110 receive the serial data stream (S_DATA) having data being haptic data. In yet another example, the speakers 125, 130 produce ultra sonic signals having frequencies in the ultrasonic spectrum (e.g., greater than 20kHz) for ultrasonic sensing. Control proceeds to return to Block 505.

Although example methods are described with reference to the flowchart illustrated in FIG. 5, many other methods of implementing the serializers 405, 420 and the deserializers 410, 425 of FIG. 4 and the channels 105, 110 of FIG. 4 or, more generally, the audio system 100 of FIG. 4 may alternatively be used in this description. For example, the order of execution of the blocks may be changed, and/or some of the blocks described may be changed, eliminated, or combined. Similarly, additional operations may be included in the manufacturing process before, in between, or after the blocks shown in the illustrated examples.

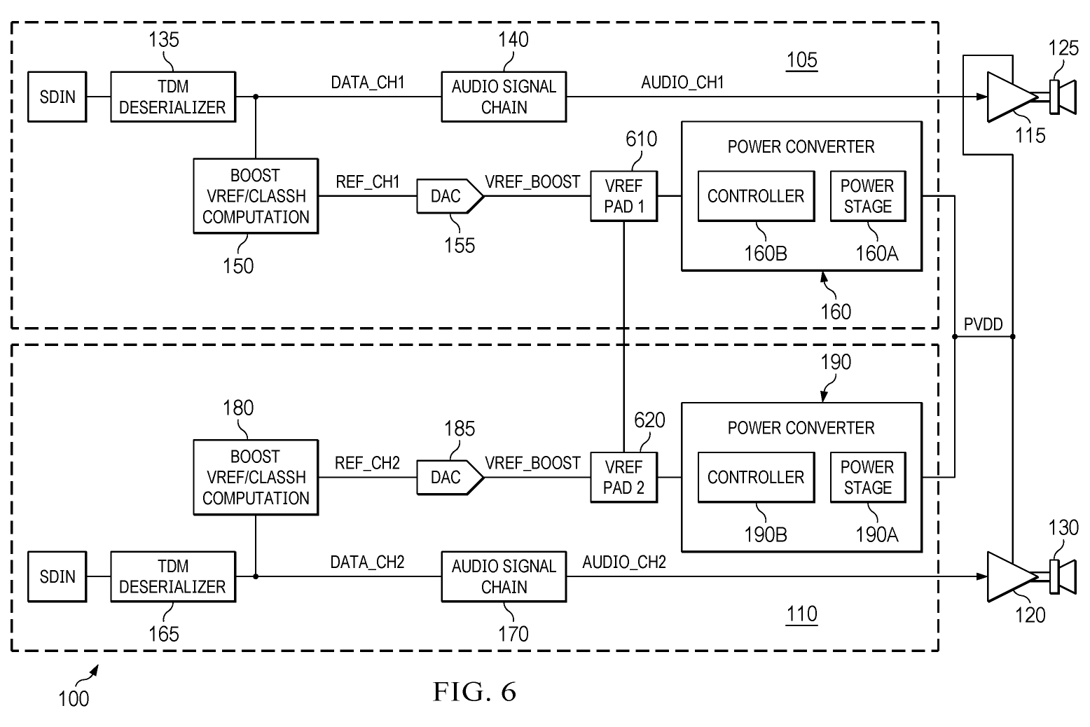

FIG. 6 is a block diagram of another example of the audio system 100 of FIG. 1 having the channels 105, 110, according to an embodiment of the present disclosure. In the example of FIG. 6, the audio system 100 includes the channels 105, 110, the amplifiers 115, 120, and the speakers 125, 130. The example audio system 100 of FIG. 6 receives a serial data stream (S_DATA) at a serial interface input (SDIN). Unlike in the examples of FIGS. 1 and 2, the example audio system 100 of FIG. 6 uses an additional connection between the channels 105, 110. As further described below, the channels 105, 110 use the additional connection to share the boost reference voltage (VREF_BOOST) between the channels. The audio system 100 produces audible sound responsive to data of the serial data stream (S_DATA) and by sharing the boost reference voltage (VREF_BOOST) across the channels 105, 110.

The channel 105 is coupled to the channel 110 and the amplifier 115. The example channel 105 of FIG. 6 includes the deserializer 135, the audio signal chain circuitry 140, the boost determination logic 150, the DAC 155, the power converter 160, and a reference terminal 610 (also referred to as a reference pad, node, etc.). The channel 105 receives the serial data stream (S_DATA). The channel 105 generates an audio signal (AUDIO_CH1) and a supply voltage (PVDD). In some examples, the channel 105 sets the boost reference voltage (VREF_BOOST) responsive to the audio data signal (DATA_CH1) of the serial data stream (S_DATA). In other examples, the channel 105 receives the boost reference voltage (VREF_BOOST) responsive to the audio data signal (DATA_CH2) of the channel 110 having a greater peak.

In operation, the boost determination logic 150 determines the supply voltage (PVDD) to support the audio data signal (DATA_CH1). The boost determination logic 150 generates the channel reference (REF_CH1) representing the determined supply voltage needed for the audio data signal (DATA_CH1). The DAC 155 attempts to set the reference terminal 610 to a voltage corresponding to the channel reference (REF_CH1). However, if the channel reference (REF_CH2) of the channel 110 is greater than the channel reference (REF_CH1) of the channel 105, the channel 110 sets the reference terminal 610 to a voltage based on the channel reference (REF_CH2). In such operations, the voltage at the reference terminal 610 is referred to as the boost reference voltage (VREF_BOOST). Similar to the operations of FIGS. 1, 2, and 4, the power converter 160 produces the supply voltage (PVDD) responsive to the boost reference voltage (VREF_BOOST).

The channel 110 is coupled to the channel 105 and the amplifier 120. The example channel 110 of FIG. 4 includes the deserializer 165, the audio signal chain circuitry 170, the boost determination logic 180, the DAC 185, the power converter 190, and a reference terminal 620 (also referred to as a reference pad, node, etc.). The channel 110 receives the serial data stream (S_DATA). The channel 110 generates an audio signal (AUDIO_CH2) and a supply voltage (PVDD). In some examples, the channel 110 sets the boost reference voltage (VREF_BOOST) responsive to the audio data signal (DATA_CH2) of the serial data stream (S_DATA). In other examples, the channel 110 receives the boost reference voltage (VREF_BOOST) responsive to the audio data signal (DATA_CH1) of the channel 105 having a greater peak.

In operation, the boost determination logic 180 determines the supply voltage (PVDD) to support the audio data signal (DATA_CH2). The boost determination logic 180 generates the channel reference (REF_CH2) representing the determined supply voltage needed for the audio data signal (DATA_CH2). The DAC 185 attempts to set the reference terminal 620 to a voltage corresponding to the channel reference (REF_CH2). However, if the channel reference (REF_CH1) of the channel 105 is greater than the channel reference (REF_CH2) of the channel 110, the channel 105 sets the reference terminal 620 to a voltage based on the channel reference (REF_CH1). In such operations, the voltage at the reference terminal 620 is referred to as the boost reference voltage (VREF_BOOST). Similar to the operations of FIGS. 1, 2, and 4, the power converter 190 produces the supply voltage (PVDD) responsive to the boost reference voltage (VREF_BOOST).

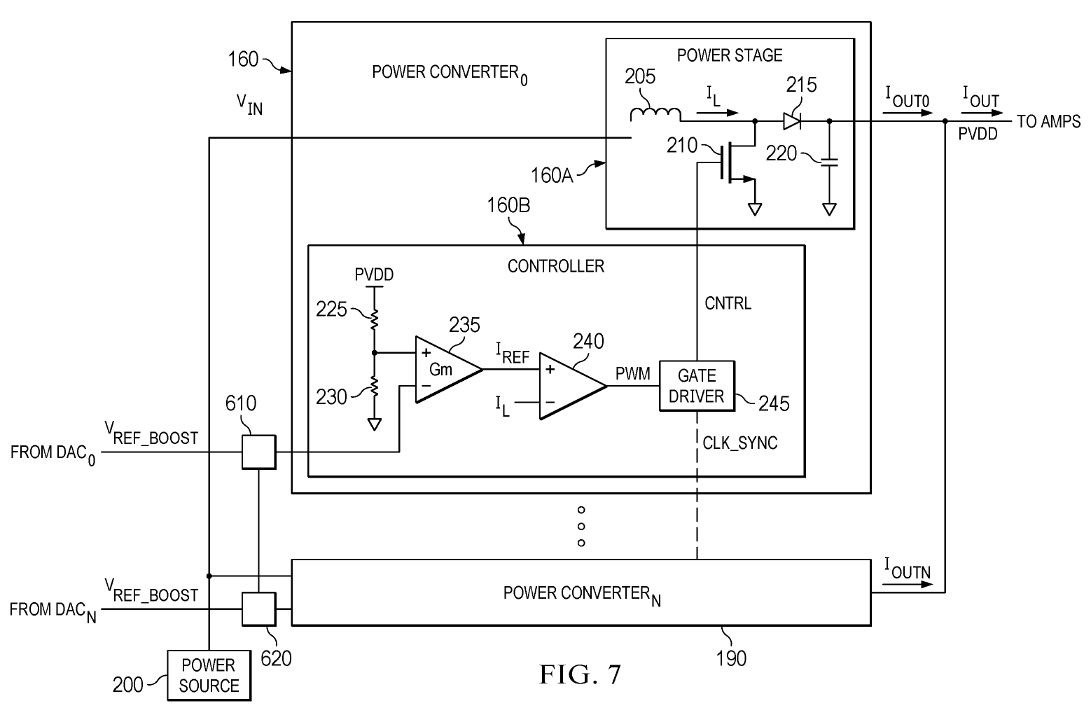

FIG. 7 is a schematic diagram of an example implementation of the power converters 160, 190 of FIG. 6, according to an embodiment of the present disclosure. The power converters 160, 190 convert power from the power supply 200 to provide the supply current (I_{OUT}) and the supply voltage (PVDD). In the example of FIG. 7, the reference terminals 610, 620 are coupled to the power converters 160, 190. The reference terminals 610, 620 provide the boost reference voltage (VREF_BOOST).

In operation, the controller 160B generates the control signal (CNTRL) responsive to a comparison of the boost reference voltage (VREF_BOOST) to the supply voltage (PVDD) and the current (I_{L}). The power stage 160A generates the supply voltage (PVDD) and the stage supply current (I_{OUT0}) responsive to the control signal (CNTRL). Similarly, corresponding components of the power converter 190 set the supply voltage (PVDD) responsive to the boost reference voltage (VREF_BOOST) at the reference terminals 610, 620.

In some embodiments, coupling the reference terminals 610, 620 together advantageously reduces the complexity of determining a peak across the channels 105, 110. In some embodiments, using a shared boost reference voltage (VREF_BOOST) at the reference terminals 610, 620 advantageously increases a likelihood that the power converters 160, 190 receive the same boost reference voltage (VREF_BOOST).

While an example manner of implementing the channels 105, 110 are illustrated in FIGS. 1, 4, and 6, one or more of the elements, processes, and/or devices illustrated in FIGS. 1, 4, and 6, may be combined, divided, re-arranged, omitted, eliminated, and/or implemented in any other way. Further, the deserializers 135, 165, 410, 425, the audio signal chain circuitry 140, 170, the peak detectors 145, 175, 415, 430, the DACs 155, 185, and/or the serializers 405, 420, and/or, more generally, the example channels 105, 110 of FIGS. 1, 4, and 6, may be implemented by hardware alone or by hardware in combination with software and/or firmware. Thus, for example, any of the deserializers 135, 165, 410, 425, the audio signal chain circuitry 140, 170, the peak detectors 145, 175, 415, 430, the DACs 155, 185, and/or the serializers 405, 420, and/or, more generally, the example channels 105, 110, could be implemented by programmable circuitry, processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), vision processing units (VPUs), and/or field programmable logic device(s) (FPLD(s)) such as FPGAs in combination with machine readable instructions (e.g., firmware or software). Further still, the example channels 105, 110 of FIGS. 1, 4, and 6, may include one or more elements, processes, and/or devices in addition to, or instead of, those illustrated in FIGS. 1, 4, and 6, and/or may include more than one of any or all of the illustrated elements, processes and devices.

Methods 300 and/or 500 may be executed or performed by programmable circuitry to implement and/or instantiate the channels 105, 110 of FIGS. 1, 4, and 6.

A program for performing methods 300 and/or 500 may be embodied in instructions (e.g., software and/or firmware) stored on one or more non-transitory computer readable and/or machine readable storage medium.

Although methods 300 and 500 are described with reference to the flowchart(s) illustrated in FIGS. 3 and 5, many other methods of implementing the example channels 105, 110 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)).

As used herein, programmable circuitry includes any type(s) of circuitry that may be programmed to perform a desired function such as, for example, a CPU, a GPU, a VPU, and/or an FPGA. The programmable circuitry may include one or more CPUs, one or more GPUs, one or more VPUs, and/or one or more FPGAs located in the same package (e.g., the same integrated circuit (IC) package or in two or more separate housings), one or more CPUs, GPUs, VPUs, and/or one or more FPGAs in a single machine, multiple CPUs, GPUs, VPUs, and/or FPGAs distributed across multiple servers of a server rack, and/or multiple CPUs, GPUs, VPUs, and/or FPGAs distributed across one or more server racks. Additionally or alternatively, programmable circuitry may include a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc., and/or any combination(s) thereof in any of the contexts explained above.

Circuits described herein may be reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated.

Modifications are possible in the described embodiments, and other embodiments are possible, within the scope of the claims.

Example embodiments of the present disclosure are summarized here. Other embodiments can also be understood from the entirety of the specification and the claims filed herein.

Example 1. An electronic circuit including: a first voltage regulator; a first deserializer configured to receive a first signal that includes first data associated with a first channel; and a first controller configured to: identify a first temporal peak between a peak associated with the first data and a peak associated with second data associated with a second channel; and provide to the first voltage regulator a reference voltage that is based on the first temporal peak.

Example 2. The electronic circuit of example 1, where the first voltage regulator is a boost switching converter.

Example 3. The electronic circuit of one of examples 1 or 2, where the first signal includes the second data.

Example 4. The electronic circuit of one of examples 1 to 3, where the first data is first audio data, and the second data is second audio data.

Example 5. The electronic circuit of one of examples 1 to 4, where the first signal further includes third data associated with a third channel, the third data being haptic data.

Example 6. The electronic circuit of one of examples 1 to 5, further including a first amplifier configured to reproduce the first data, the first amplifier having a supply terminal coupled to an output of the first voltage regulator.

Example 7. The electronic circuit of one of examples 1 to 6, further including a second amplifier configured to reproduce the second data, the second amplifier having a supply terminal coupled to the output of the voltage regulator.

Example 8. The electronic circuit of one of examples 1 to 7, further including: a second deserializer configured to receive the first signal; and a second voltage regulator having an output coupled to the output of the first voltage regulator.

Example 9. The electronic circuit of one of examples 1 to 8, further including a second controller configured to: identify a second temporal peak between a peak associated with the first data and a peak associated with the second data; and provide to the second voltage regulator a reference voltage that is based on the second temporal peak.

Example 10. The electronic circuit of one of examples 1 to 9, where the first deserializer, the first controller, and the first voltage regulator are integrated in a first integrated circuit (IC), the second deserializer, the second controller, and the second voltage regulator are integrated in a second IC.

Example 11. The electronic circuit of one of examples 1 to 10, where the first amplifier is integrated in a third IC, and the second amplifier is integrated in a fourth IC.

Example 12. The electronic circuit of one of examples 1 to 11, where the first controller includes a digital to analog converter (DAC) configured to provide the reference voltage to the first voltage regulator.

Example 13. The electronic circuit of one of examples 1 to 12, where the DAC has an output coupled to a reference terminal, where the first controller is configured to identify the first temporal peak by summing an output of the DAC with another signal received at the reference terminal.

Example 14. The electronic circuit of one of examples 1 to 13, further including: a first serializer having an output configured to provide a first reference code associated with the first data; and a second deserializer having an input coupled to the output of the first serializer, the second deserializer configured to receive a second reference code associated with the second data, where the first controller configured to identify the first temporal peak based on the first and second reference codes.

Example 15. The electronic circuit of one of examples 1 to 14, further including a second deserializer configured to receive the first signal including the first and second data.

Example 16. The electronic circuit of one of examples 1 to 15, where the first controller is further configured to: track an envelope of the first data; and identify the first temporal peak using the envelope of the first data.

Example 17. The electronic circuit of one of examples 1 to 16, further including: a first DAC having an output, the first DAC configured to generate the reference voltage responsive to the first temporal peak; a second voltage regulator having an input; and a second DAC having an output coupled to the output of the first DAC and the input of the first voltage regulator and the input of the second voltage regulator, the second DAC configured to generate a second reference voltage responsive to a second temporal peak of the second data.

Example 18. The electronic circuit of one of examples 1 to 17, further including a second controller coupled to the first controller, the second controller configured to: determine a first reference code associated with a second temporal peak of the second data; and provide the first reference code to the first controller.

Example 19. The electronic circuit of one of examples 1 to 18, where the first controller is further configured to: determine a second reference code associated with the first temporal peak of the first data; receive the first reference code from the second controller; and determine the reference voltage based on a comparison of the first and second reference codes.

Example 20. The electronic circuit of one of examples 1 to 19, where the first temporal peak is a local peak of the first data and the second data.

Example 21. The electronic circuit of one of examples 1 to 20, where the first data is a first digital audio signal and the second data is a second digital audio signal.

Example 22. The electronic circuit of one of examples 1 to 21, where the first data is a first analog audio signal and the second data is a second analog audio signal.

Example 23. The electronic circuit of one of examples 1 to 22, further including: a second voltage regulator having an output coupled to an output of the first voltage regulator; and a second controller coupled to the second voltage regulator, the second controller configured to synchronize a switching phase of the first voltage regulator with the second voltage regulator.

Example 24. The electronic circuit of one of examples 1 to 23, where the first and second controllers are configured to synchronize the switching phase of the first and second voltage regulators based on the first signal.

Example 25. An apparatus including: a first device including: a first input terminal; a first deserializer having an input coupled to the first input terminal and an output; and a first voltage regulator having an input and an output, the input of the first voltage regulator coupled to the output of the first deserializer; a second device including: a second input terminal; a second deserializer having an input and an output, the input of the second deserializer coupled to the second input terminal; and a second voltage regulator having an input and an output, the input of the second voltage regulator coupled to the output of the second deserializer, the output of the second voltage regulator coupled to the output of the first voltage regulator; a first amplifier having a data input and a supply input, the supply input of the first amplifier coupled to the outputs of the first and second voltage regulators, the data input of the first amplifier coupled to the output of the first deserializer; and a second amplifier having a data input and a supply input, the data input of the second amplifier coupled to the outputs of the first and second voltage regulators, the data input of the second amplifier coupled to the output of the second deserializer.

Example 26. The apparatus of example 25, further including a digital bus coupled to the first and second devices.

Example 27. The apparatus of one of examples 25 or 26, where the digital bus is coupled to the first input terminal of the first device and to the second input terminal of the second device.

Example 28. The apparatus of one of examples 25 to 27, where: the first device includes a first output coupled to the output of the first deserializer; and the second device includes a second output coupled to the output of the second deserializer, where the digital bus is coupled between the first output and the second output.

Example 29. The apparatus of one of examples 25 to 28, where: the first device includes: a first digital to analog converter (DAC) having an input and an output, the input coupled to the output of the first deserializer; and a first pad having an input and an output, the input coupled to the output of the first DAC, the output coupled to the input of the first voltage regulator; the second device includes: a second DAC having an input and an output, the input coupled to the output of the second deserializer; and a second pad having an input and an output, the input coupled to the output of the DAC, the output coupled to the input of the second voltage regulator; and a digital bus coupled between the first pad and the second pad.

Example 30. The apparatus of one of examples 25 to 29, where: the first amplifier has an output; a first speaker coupled to the output of the first amplifier; the second amplifier has an output; and a second speaker coupled to the output of the second amplifier.

Example 31. A method including: receiving first data and second data from a first serial input stream and a second serial input stream, respectively; identifying a first supply voltage corresponding to the first data is greater than or less than a second supply voltage corresponding to the second data; selecting the first supply voltage as a maximum supply voltage when the first supply voltage is greater than the second supply voltage; generating a regulator output voltage based on the selected first supply voltage; and amplifying the first and second data using the regulator output voltage.

Example 32. The method of example 31, further including receiving the first and second serial input streams in a time multiplexed manner at a first input terminal.

Example 33. The method of one of examples 31 or 32, where identifying the first supply voltage is greater than or less than the second supply voltage includes communicating second audio data through the first serial input stream to a first device receiving the first data.

Example 34. The method of one of examples 31 to 33, where identifying the first supply voltage is greater than or less than the second supply voltage includes communicating second audio data, via a serial output stream, to a first device receiving the first data.

Example 35. The method of one of examples 31 to 34, where identifying the first supply voltage is greater than or less than the second supply voltage includes communicating the second supply voltage, via a digital bus, to a first device receiving the first data.

While this disclosure has been described with reference to illustrative embodiments, this description is not limiting. Various modifications and combinations of the illustrative embodiments, as well as other embodiments, will be apparent to persons skilled in the art upon reference to the description.

What is claimed is:

1. An electronic circuit comprising:
a first voltage regulator;
a first deserializer configured to receive a first signal that includes first data associated with a first channel; and
a first controller configured to:
identify a first temporal peak between a peak associated with the first data and a peak associated with second data associated with a second channel; and
provide to the first voltage regulator a reference voltage that is based on the first temporal peak.

2. The electronic circuit of claim 1, wherein the first voltage regulator is a boost switching converter.

3. The electronic circuit of claim 1, wherein the first signal includes the second data.

4. The electronic circuit of claim 3, wherein the first data is first audio data, and the second data is second audio data.

5. The electronic circuit of claim 4, wherein the first signal further includes third data associated with a third channel, the third data being haptic data.

6. The electronic circuit of claim 1, further comprising a first amplifier configured to reproduce the first data, the first amplifier having a supply terminal coupled to an output of the first voltage regulator.

7. The electronic circuit of claim 6, further comprising a second amplifier configured to reproduce the second data, the second amplifier having a supply terminal coupled to the output of the voltage regulator.

8. The electronic circuit of claim 7, further comprising:
a second deserializer configured to receive the first signal; and
a second voltage regulator having an output coupled to the output of the first voltage regulator.

9. The electronic circuit of claim 8, further comprising a second controller configured to:
identify a second temporal peak between a peak associated with the first data and a peak associated with the second data; and
provide to the second voltage regulator a reference voltage that is based on the second temporal peak.

10. The electronic circuit of claim 9, wherein the first deserializer, the first controller, and the first voltage regulator are integrated in a first integrated circuit (IC), the second deserializer, the second controller, and the second voltage regulator are integrated in a second IC.

11. The electronic circuit of claim 10, wherein the first amplifier is integrated in a third IC, and the second amplifier is integrated in a fourth IC.

12. The electronic circuit of claim 1, wherein the first controller comprises a digital to analog converter (DAC) configured to provide the reference voltage to the first voltage regulator.

13. The electronic circuit of claim 12, wherein the DAC has an output coupled to a reference terminal, wherein the first controller is configured to identify the first temporal peak by summing an output of the DAC with another signal received at the reference terminal.

14. The electronic circuit of claim 1, further comprising:
a first serializer having an output configured to provide a first reference code associated with the first data; and
a second deserializer having an input coupled to the output of the first serializer, the second deserializer configured to receive a second reference code associated with the second data, wherein the first controller configured to identify the first temporal peak based on the first and second reference codes.

15. The electronic circuit of claim 1, further comprising a second deserializer configured to receive the first signal including the first and second data.

16. The electronic circuit of claim 1, wherein the first controller is further configured to:
track an envelope of the first data; and
identify the first temporal peak using the envelope of the first data.

17. The electronic circuit of claim 1, further comprising:
a first DAC having an output, the first DAC configured to generate the reference voltage responsive to the first temporal peak;
a second voltage regulator having an input; and
a second DAC having an output coupled to the output of the first DAC and the input of the first voltage regulator and the input of the second voltage regulator, the second DAC configured to generate a second reference voltage responsive to a second temporal peak of the second data.

18. The electronic circuit of claim 1, further comprising a second controller coupled to the first controller, the second controller configured to:
determine a first reference code associated with a second temporal peak of the second data; and
provide the first reference code to the first controller.

19. The electronic circuit of claim 18, wherein the first controller is further configured to: determine a second reference code associated with the first temporal peak of the first data;
receive the first reference code from the second controller; and
determine the reference voltage based on a comparison of the first and second reference codes.

20. The electronic circuit of claim 1, wherein the first temporal peak is a local peak of the first data and the second data.

21. The electronic circuit of claim 1, wherein the first data is a first digital audio signal and the second data is a second digital audio signal.

22. The electronic circuit of claim 1, wherein the first data is a first analog audio signal and the second data is a second analog audio signal.

23. The electronic circuit of claim 1, further comprising:
a second voltage regulator having an output coupled to an output of the first voltage regulator; and
a second controller coupled to the second voltage regulator, the second controller configured to synchronize a switching phase of the first voltage regulator with the second voltage regulator.

24. The electronic circuit of claim 23, wherein the first and second controllers are configured to synchronize the switching phase of the first and second voltage regulators based on the first signal.
